(19) United States
(12) Patent Application Publication
(10) Pub. No.: US 2007/0230113 A1
(43) Pub. Date: Oct. 4, 2007

(54) Rackmount server with fans installed next to a side of a housing

(75) Inventor: Chin-Chun Chiang, Taipei City (TW)

Correspondence Address: BIRCH, STEWART, KOLASCH & BIRCH, LLP, 8110 GATEHOUSE ROAD, SUITE 100 EAST, FALLS CHURCH, VA, 22315, US

(73) Assignee: ASUSTeK COMPUTER INC.

(21) Appl. No.: 11/604,211

(22) Filed: Nov. 27, 2006

(30) Foreign Application Priority Data
Mar. 30, 2006 (TW) 095111295

(51) Int. Cl. G06F 1/20; H05K 5/00

(52) U.S. Cl. 361/687; 361/724; 361/686

(57) ABSTRACT

A 1U rackmount computer includes a housing including a plurality of vents at a side, a power supply area including a power supply module, a fan area including at least one fan installed at a side of the plurality of vents for dissipating heat generated by a plurality of components out of the housing via the plurality of vents, and an external port installed on the side with the plurality of vents of the housing for connecting an external device.

### BACKGROUND OF THE INVENTION

1. Field of the Invention

The present invention relates to a 1U rackmount server, and more particularly, to a 1U rackmount server with fans installed next to a side of a housing.

2. Description of the Prior Art

In progress of computers and network, servers are utilized widely in common industry. A 1U rackmount server has an advantage of small size so as to be arranged conveniently in a machine room.

There is only a side of the 1U rackmount server capable of disposing vents for dissipating heat because the 1U rackmount servers are always piled up and there are slots on lateral sides of the 1U rackmount server for installing on a frame. In addition, the lateral sides of the 1U rackmount server are neighboring to other 1U rackmount servers. Please refer to FIG. 1. FIG. 1 is a diagram of 1U rackmount servers disposed in a machine room in the prior art. A plurality of 1U rackmount servers 111, 112, 113, 114, 115 is arranged in a stack. Vents only can be disposed on outer sides of the 1U rackmount servers 111, 112, 113, 114, 115 for dissipating heat. However a user interface, such as input/output ports, or a socket for connecting a detachable device is also disposed on the outer sides. Hence there is a limitation in disposing vents on the outer sides so as to reduce heat-dissipating efficiency, stability, and service life of the 1U rackmount servers.

Please refer to FIG. 2. FIG. 2 is an outer diagram of the 1U rackmount server 112 in the prior art. A power supply port 231, two PS/2 ports 2321, 2322, two USB ports 2331, 2332, a RS232 port 234, a VGA port 235, two network ports 236, 237, two external sockets 241, 242, a fan 210 of a power supply module, and three heat-dissipating areas 221, 222, 223 are disposed on a lateral side 20 of the 1U rackmount server 112. Because there are many connect ports disposed on the lateral side 20 of the 1U rackmount server 112, there is limited area for disposing small vents of the heat-dissipating areas 221, 222, 223 and there is no extra area for disposing other vents corresponding to fans to dissipate heat. Although the fan 210 can dissipate heat generated by the power supply module at most, heat generated by other internal components of the 1U rackmount server 112, such as a central processing unit or a hard disk, can not be dissipated efficiently via the small vents of the heat-dissipating areas 221, 222, 223 without fans.

Please refer to FIG. 3. FIG. 3 is an inner diagram of the 1U rackmount server 112 in the prior art. The 1U rackmount server 112 includes a power supply module 250. The fan 210 can dissipate heat generated by the power supply module 250. The 1U rackmount server 112 further includes a motherboard 260. There are sockets 261 to 266 disposed on the motherboard 260. The 1U rackmount server 112 further includes fans 211 to 215 in a middle section of the 1U rackmount server 112. As above-mentioned description, there is no extra area on the lateral side 20 for disposing vents corresponding to fans to dissipate heat, so the fans 211 to 215 are disposed in the middle section of the 1U rackmount server 112 for dissipating heat generated by internal components, such as the central processing unit or the hard disk. However there is no heat-dissipating vent nearby the fans 211 to 215 for dissipating hot air. There is a need to utilize a high-speed fan to increase heat-dissipating efficiency so that it increases a cost and noise but can not dissipate heat efficiently in expectation.

### SUMMARY OF THE INVENTION

It is therefore an objective of the claimed invention to provide a 1U rackmount server with fans installed next to a side of a housing for solving the above-mentioned problem.

According to the claimed invention, a 1U rackmount computer includes a housing including a plurality of vents at a side, a power supply area including a power supply module, a fan area including at least one fan installed at a side of the plurality of vents for dissipating heat generated by a plurality of components out of the housing via the plurality of vents, and an external port installed on the side with the plurality of vents of the housing for connecting an external device.

According to the claimed invention, a 1U rackmount computer includes a housing including a plurality of vents at a side, a power supply area including a power supply module, a fan area including at least one fan installed at a side of the plurality of vents for dissipating heat out of the housing via the plurality of vents, an external port installed on the side with the plurality of vents of the housing, and an extended port device connected to the external port. The extended port device includes an upper stream port connected to the external port, and a lower stream port for connecting an external device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of 1U rackmount servers disposed in a machine room in the prior art.

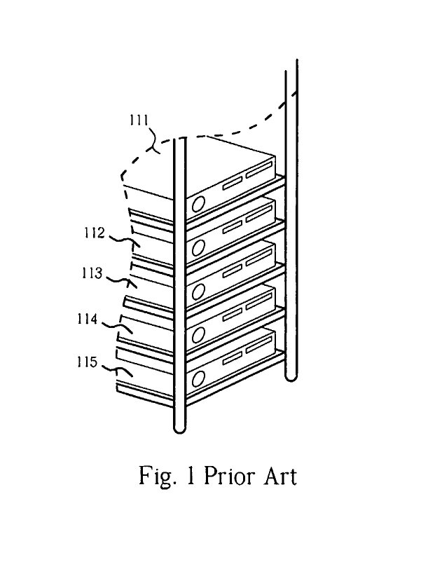

FIG. 2 is an outer diagram of the 1U rackmount server in the prior art.

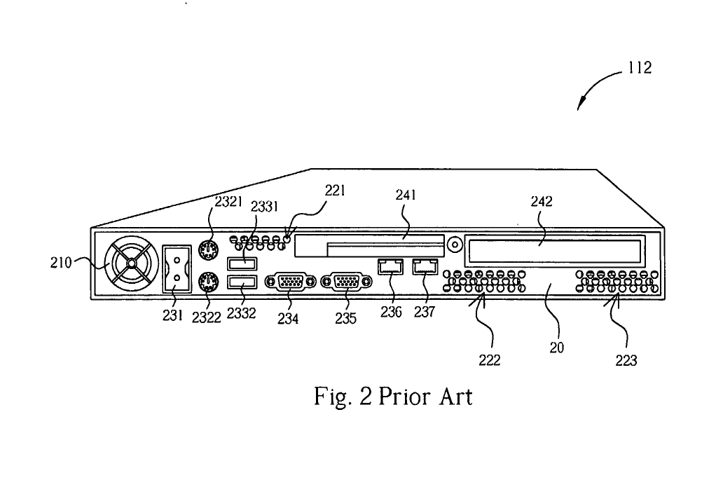

FIG. 3 is an inner diagram of the 1U rackmount server in the prior art.

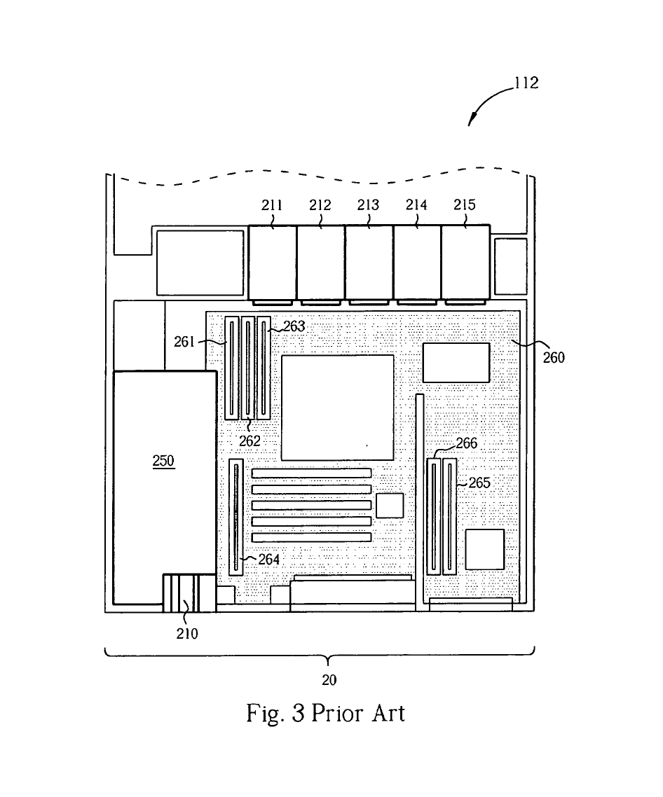

FIG. 4 is an inner diagram of a 1U rackmount server according to the present invention.

FIG. 5 is a diagram of the 1U rackmount server connecting with an extended port device according to the present invention.

### DETAILED DESCRIPTION

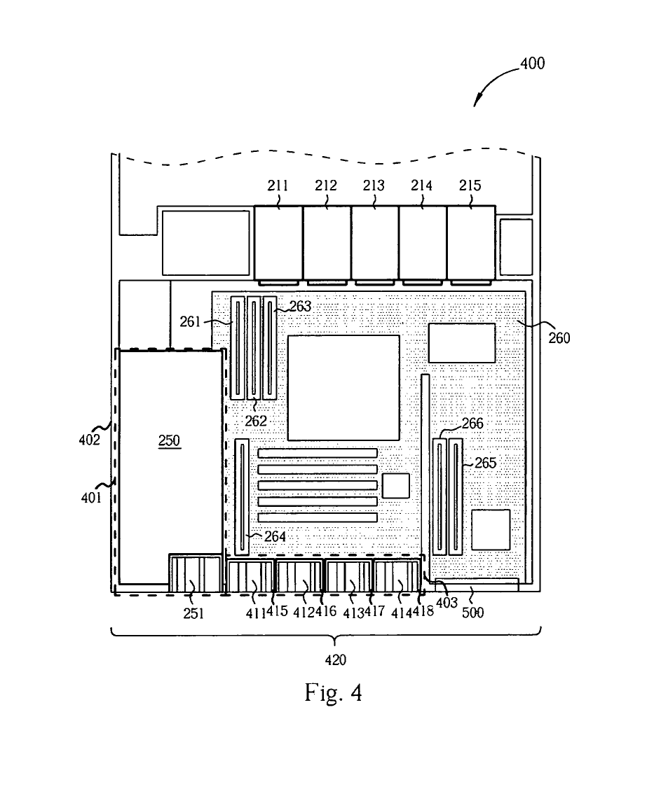

Please refer to FIG. 4. FIG. 4 is an inner diagram of a 1U rackmount server 400 according to the present invention. The 1U rackmount server 400 includes a power supply area 401. A power supply module 250 and a power supply fan 251 are disposed in the power supply area 401. The power supply fan 251 can dissipate heat generated by the power supply module 250. The 1U rackmount server 400 further includes fans 211 to 215 in a middle section of the 1U rackmount server 400. A plurality of vents 415, 416, 417, 418 is disposed on a lateral side 420 of a housing 402 of the 1U rackmount server 400. The 1U rackmount server 400 further includes a fan area 403. A plurality of fans 411, 412, 413, 414 is disposed at a side of the plurality of vents 415, 416, 417, 418 in the fan area 403 for dissipating heat generated by a plurality of components out of the housing 402 via the plurality of vents 415, 416, 417, 418. Therefore an area disposing connect ports is limited within an external port area 500. A width of the 1U rackmount computer 400 is about 44.5 cm due to limitation of a width of a frame for supporting the 1U rackmount computer 400. A width of the power supply module 250 is about 10 cm, and a width of the fan is about 4 cm. In this embodiment, there are about seven to eight fans for dissipating heat at a condition of preserving one external port area 500. The heat-dissipating efficiency can be increased by disposing more fans and noise can be reduced by lowering revolving speed of the fans. The present invention utilizes a fan area 403 for disposing at least one fan to dissipate heat on the lateral side of the 1U rackmount server 400.

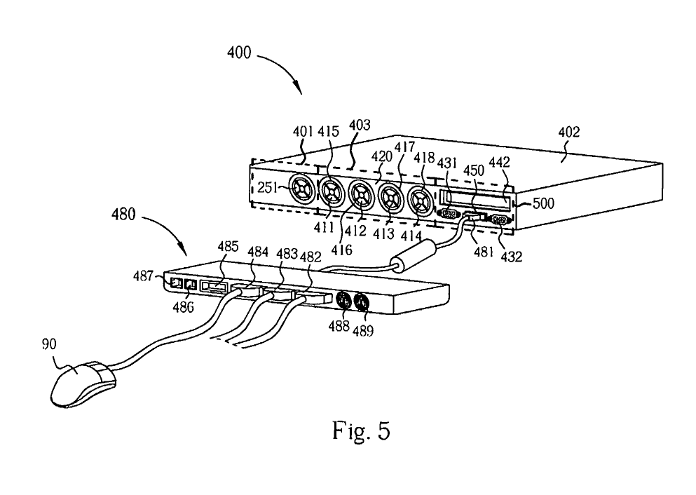

Please refer to FIG. 5. FIG. 5 is a diagram of the 1U rackmount server 400 connecting with an extended port device according to the present invention. As shown in FIG. 4 and FIG. 5, there are only some basic connect ports, such as a RS232 port 431, a VGA port 432, or an external socket 442, disposed on the external port area 500 on the lateral side 420 of the housing 402 of the 1U rackmount server 400. The basic connect ports disposed on the external port area 500 can be designed by demand. The rest area is reserved to dispose the plurality of vents 415, 416, 417 corresponding to the plurality of fans 411, 412, 413, 414 so as to dissipate heat generated by a central processing unit or a hard disk (not shown in figures) out of the housing 402. The 1U rackmount server 400 further includes an extended port device 480. The extended port device 480 includes an upper stream port 481 for connecting to an external port 450 on the lateral side 420 of the housing 402 and a plurality of lower stream ports 482 to 489 for connecting different external devices. The standard of the lower stream ports can be designed by demand. For example, the lower stream port 484 corresponding with a USB standard is connected to a USB mouse 90. The extended port device 480 can extend connection between the 1U rackmount server 400 and external devices so as to enlarge the area on the lateral side 420 for disposing the vents corresponding to the fans to dissipate heat out of the housing 402. It can increase heat-dissipating efficiency of the 1U rackmount server 400. The extended port device 480 can be fixed to the 1U rackmount server 400 directly without utilizing the upper stream port 481.

In contrast to the conventional 1U rackmount server, the 1U rackmount server according to the present invention removes connect ports and sockets from the lateral side of the housing to the extended port device so as to enlarge the area on the lateral side for disposing the vents corresponding to the fans to dissipate heat out of the housing. It can increase a heat-dissipating efficiency of the 1U rackmount server so as to increase stability and service life of the 1U rackmount servers. The 1U rackmount server according to the present invention utilizes more vents and corresponding fans to dissipate heat, so there is no need to utilize a high-speed fan so as to reduce a cost and noise.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A 1U rackmount computer comprising:
a housing comprising a plurality of vents at a side;
a power supply area comprising a power supply module;
a fan area comprising at least one fan installed at the side of the plurality of vents for dissipating heat generated by a plurality of components out of the housing via the plurality of vents; and
an external port installed on the side with the plurality of vents of the housing for connecting an external device.

2. The 1U rackmount computer of claim 1 wherein the power supply area further comprises a power supply fan for dissipating heat generated by the power supply module.

3. The 1U rackmount computer of claim 1 further comprising an extended port device connected to the external port, the extended port device comprising:
an upper stream port connected to the external port; and at least one lower stream port for connecting an external device corresponsively.

4. The 1U rackmount computer of claim 1 further comprising a central processing unit installed inside the housing and nearby the fan area.

5. The 1U rackmount computer of claim 1 wherein a width of the 1U rackmount computer is 44.5 cm substantially, a width of the power supply module is 10 cm substantially, and a width of the fan is 4 cm substantially.

6. The 1U rackmount computer of claim 5 wherein the fan area comprises seven to eight fans.

7. The 1U rackmount computer of claim 1 being a 1U rackmount slim server.

8. A 1U rackmount computer comprising:
a housing comprising a plurality of vents at a side;
a power supply area comprising a power supply module;
a fan area comprising at least one fan installed at a side of the plurality of vents for dissipating heat out of the housing via the plurality of vents;
an external port installed on the side with the plurality of vents of the housing; and
an extended port device connected to the external port, the extended port device comprising:
an upper stream port connected to the external port; and;
a lower stream port for connecting an external device.

9. The 1U rackmount computer of claim 8 wherein the power supply area further comprises a power supply fan for dissipating heat generated by the power supply module.

10. The 1U rackmount computer of claim 8 wherein the extended port device comprises a plurality of lower stream ports for connecting a plurality of external devices.

11. The 1U rackmount computer of claim 8 further comprising a central processing unit installed inside the housing and nearby the fan area.

12. The 1U rackmount computer of claim 8 being a 1U rackmount slim server.

13. The 1U rackmount computer of claim 8 wherein a width of the 1U rackmount computer is 44.5 cm substantially, a width of the power supply module is 10 cm substantially, and a width of the fan is 4 cm substantially.

14. The 1U rackmount computer of claim 13 wherein the fan area comprises seven to eight fans.
